(19) United States
(12) Patent Application Publication
(10) Pub. No.: US 2026/0214780 A1
(43) Pub. Date: Jul. 23, 2026

(54) Discharge and Modulation System and Method for Microwave-Radio Frequency (RF) Mixed Coupled Plasma

(71) Applicant: National University of Defense Technology, Changsha City (CN)

(72) Inventors: Feng SHI, Changsha City (CN); Gang ZHOU, Changsha City (CN); Shuo QIAO, Changsha City (CN); Ye TIAN, Changsha City (CN); Shuangpeng GUO, Changsha City (CN); Lingbo XIE, Changsha City (CN)

(21) Appl. No.: 19/398,862

(22) Filed: Nov. 24, 2025

(30) Foreign Application Priority Data
Jan. 17, 2025 (CN) 202510081991.9

(51) Int. Cl. H05H 1/54; H05H 1/46

(52) U.S. Cl. CPC H05H 1/54; H05H 1/463; H05H 1/4652

(57) ABSTRACT

Provided are a discharge and modulation system and method for a microwave-radio frequency (RF) mixed coupled plasma, which relate to the technical field of ion beam processing. A gas distributor delivers a process gas separately to an Electron Cyclotron Resonance (ECR) region and an RF-enhanced discharge chamber. A power of a microwave antenna is adjusted to enable the process gas in the ECR region to form an initial plasma. A voltage of an electron extraction grid is adjusted to extract an electron from the initial plasma into the RF-enhanced discharge chamber. An RF power supply loads an RF voltage onto an RF coil, such that the electron collides with the process gas in the RF-enhanced discharge chamber, thereby forming a high-density plasma. An ion extraction grid is adjusted to enable an ion within the high-density plasma to form an ion beam current.

### CROSS REFERENCE TO RELATED APPLICATION

This patent application claims the benefit and priority of Chinese Patent Application No. 2025100819919, filed with the China National Intellectual Property Administration on Jan. 17, 2025, the disclosure of which is incorporated by reference herein in its entirety as part of the present application.

### TECHNICAL FIELD

The present disclosure relates to the technical field of ion beam processing, and in particular, to a discharge and modulation system and method for a microwave-radio frequency (RF) mixed coupled plasma.

### BACKGROUND

Since the 1960s, the manufacturing of ultra-smooth optical surfaces, large-scale integrated circuits, metasurfaces, and micro-nano structures has seen significant progress, demanding a flexible and controllable ion etching process with high efficiency and stability. In recent years, plasma etching and ion beam etching technologies have been widely adopted in an ion etching process. Based on this, a Reactive Ion Etching (RIE) technology and a Reactive Ion Beam Etching (RIBE) technology that use a reactive gas as a process gas are developed. Concurrently, a Chemically Assisted Ion Beam Etching (CAIBE) technology has also achieved substantial development within the industry.

These technologies all require a high-performance ion generator with a high plasma density and a specific beam current density to achieve a high-performance plasma. This is essential for achieving a high etch selectivity ratio, a high etch rate, and etch uniformity.

In an existing ion generator, main plasma generation and modulation methods include direct current (DC) cathode heating discharge (represented by a Kaufman cathode ion source), radio frequency (RF) discharge (including inductively-coupled discharge and capacitively-coupled discharge, which are represented by the RIT series developed by the University of Giessen and an RF ion source from Veeco in the United States), and Electron Cyclotron Resonance (ECR) discharge.

However, the Kaufman cathode ion source (primarily made from LaB6 and barium tungsten) has a limited filament lifespan. Under a corrosive gas condition, a cathode lifespan is significantly reduced, and metallic ion contamination is also caused. The RF ion source avoids drawbacks related to a lifespan and contamination, but its weakness is that an electron density in a discharge chamber plays a decisive role in RF discharge and gas ionization rates. When electronegative gases such as SF₆ and O₂ are introduced, the electron density in the discharge chamber drastically decreases, causing plasma oscillation or even disappearance.

As for a microwave ion source, its drawback is high heat generation. Microwave radiation and ion collision cause a grid to heat severely. In an etching process, especially when a substrate mask is a heat-sensitive photoresist, a corresponding water-cooling measure becomes necessary. Furthermore, a microwave discharge mechanism is still under investigation, making it difficult to achieve plasma modulation.

Therefore, how to implement plasma generation and modulation within a plasma generator to meet a growing demand for surface etching has become a critical technical problem to be urgently solved.

### SUMMARY

An objective of the present disclosure is to provide a discharge and modulation system and method for a microwave-RF mixed coupled plasma, in order to solve problems of poor adaptability of an RF ion source to an electronegative gas, a low ionization rate, a low plasma density, and difficulty in achieving stable control.

To achieve the above objective, the present disclosure provides the following technical solutions.

According to a first aspect, the present disclosure provides a discharge and modulation system for a microwave-RF mixed coupled plasma, including: a gas distribution system, a plurality of power supplies, an ion beam current generation device, a Faraday cup, and a computer; where the plurality of power supplies are respectively an accelerating grid DC regulated power supply, a screen grid DC regulated power supply, an RF power supply, an electron extraction electrode DC regulated power supply, and a solid-state microwave power supply; the ion beam current generation device includes: a metal shielding enclosure with an opening at a top, and a first metal microwave shielding shell, a microwave antenna, a microwave static magnetic field, a microwave discharge chamber, an electron extraction grid, a gas distributor, a second metal microwave shielding shell, an RF coil, an RF-enhanced discharge chamber, and an ion extraction grid that are disposed inside the metal shielding enclosure; the second metal microwave shielding shell, the microwave antenna, the microwave static magnetic field, the microwave discharge chamber, and the electron extraction grid jointly enclose an ECR region; the Faraday cup is disposed in an emission direction of an ion beam current from the ion extraction grid; and the RF coil surrounds a periphery of the RF-enhanced discharge chamber;
the gas distribution system, the accelerating grid DC regulated power supply, the screen grid DC regulated power supply, the RF power supply, the electron extraction electrode DC regulated power supply, the solid-state microwave power supply, and the Faraday cup are all connected to the computer; the gas distribution system is connected to the gas distributor; and the solid-state microwave power supply is connected to the microwave antenna, the electron extraction electrode DC regulated power supply is connected to the electron extraction grid, the RF power supply is connected to the RF coil, and both the accelerating grid DC regulated power supply and the screen grid DC regulated power supply are connected to the ion extraction grid;
the computer is configured to obtain an etching requirement and determine a ratio of a process gas based on the etching requirement;
the gas distribution system is configured to store the process gas and deliver the process gas to the gas distributor based on the ratio;
the gas distributor is configured to deliver a portion of the process gas to the ECR region and deliver another portion of the process gas to the RF-enhanced discharge chamber;
the solid-state microwave power supply is configured to adjust a power of the solid-state microwave power supply under control of the computer, so as to adjust a power of the microwave antenna, such that the process gas in the ECR region discharges to form an initial plasma;
the electron extraction electrode DC regulated power supply is configured to adjust a voltage of the electron extraction electrode DC regulated power supply under the control of the computer, so as to adjust a voltage of the electron extraction grid, and extract an electron from the initial plasma into the RF-enhanced discharge chamber;
the RF power supply is configured to adjust a power of the RF power supply under the control of the computer to generate an RF voltage, and apply the RF voltage to the RF coil, such that the electron further collides with the process gas in the RF-enhanced discharge chamber to form a high-density plasma, where the high-density plasma is a plasma whose density is higher than a density of the initial plasma;
the screen grid DC regulated power supply and the accelerating grid DC regulated power supply are configured to adjust a voltage of the ion extraction grid to a voltage meeting a voltage requirement under the control of the computer, such that an ion within the high-density plasma is acceleratively extracted to form an ion beam current;
the Faraday cup is configured to measure a density of the ion beam current; and
the computer is further configured to:
determine whether the density of the ion beam current meets a stability requirement, where the stability requirement is that a density of an ion beam current output by the ion extraction grid meets a density requirement within a set period of time; and
if the density of the ion beam current meets the stability requirement, determine the ion beam current output by the ion extraction grid as a target ion beam current for etching; or
if the density of the ion beam current does not meet the stability requirement, control each of the plurality of power supplies to perform voltage or power adjustment until the density of the ion beam current meets the stability requirement, and obtain a target ion beam current.

In an implementation, the gas distribution system includes: a plurality of compressed gas cylinders, a plurality of gas mass flow controllers, and a gas mixing tank; one compressed gas cylinders is connected to one gas mass flow controller, the plurality of compressed gas cylinders are all connected to the gas mixing tank, and the gas mixing tank is connected to the gas distributor; and the plurality of gas mass flow controllers are all connected to the computer;
the computer is further configured to:
obtain a gas mass flow that is of a corresponding compressed gas cylinder and collected by each of the plurality of gas mass flow controllers; and
control each of the plurality of compressed gas cylinders to deliver a gas to the gas mixing tank based on the gas mass flow of each of the plurality of compressed gas cylinders and the ratio; and
the gas mixing tank is configured to mix the gas delivered from each of the plurality of compressed gas cylinders, obtain the process gas, and deliver the process gas to the gas distributor.

In an implementation, the gas distributor has circular holes that are uniformly distributed, and the gas distributor simultaneously delivers the process gas to the ECR region and the RF-enhanced discharge chamber through the circular holes.

In an implementation, materials of the first metal microwave shielding shell and the second metal microwave shielding shell are stainless steel or aluminum alloy.

In an implementation, the microwave static magnetic field is formed by a ring-shaped multipole high-temperature-resistant samarium-cobalt magnet, and magnetic field strength of the microwave static magnetic field is greater than 875 GS.

In an implementation, the microwave discharge chamber is made of a quartz or ceramic material.

In an implementation, the electron extraction grid is constituted by a graphite or molybdenum grid.

In an implementation, the ion extraction grid includes: a screen grid, an accelerating grid, and a decelerating grid that are disposed sequentially from bottom to top; and

the accelerating grid DC regulated power supply is connected to the accelerating grid, and the screen grid DC regulated power supply is connected to the screen grid.

In an implementation, the ion extraction grid is made of a conductive material, and the conductive material includes molybdenum, stainless steel, and graphite.

According to a second aspect, the present disclosure provides a discharge and modulation method for a microwave-RF mixed coupled plasma, implemented based on the discharge and modulation system for a microwave-RF mixed coupled plasma according to any one of the above implementations, where the discharge and modulation method for a microwave-RF mixed coupled plasma includes:
obtaining, by the computer, an etching requirement, and determining a ratio of a process gas based on the etching requirement;
delivering, by the gas distribution system, the process gas to the gas distributor based on the ratio;
delivering, by the gas distributor, a portion of the process gas to the ECR region, and delivering another portion of the process gas to the RF-enhanced discharge chamber;
adjusting, by the solid-state microwave power supply, a power of the solid-state microwave power supply under control of the computer, so as to adjust a power of the microwave antenna, such that the process gas in the ECR region discharges to form the initial plasma;
adjusting, by the electron extraction electrode DC regulated power supply, a voltage of the electron extraction electrode DC regulated power supply under the control of the computer, so as to adjust a voltage of the electron extraction grid, and extracting an electron from the initial plasma into the RF-enhanced discharge chamber;
adjusting, by the RF power supply, a power of the RF power supply under the control of the computer to generate an RF voltage, and applying the RF voltage to the RF coil, such that the electron further collides with the process gas in the RF-enhanced discharge chamber to form a high-density plasma, where the high-density plasma is a plasma whose density is higher than a density of the initial plasma;
adjusting, by the screen grid DC regulated power supply and the accelerating grid DC regulated power supply, a voltage of the ion extraction grid to a voltage meeting a voltage requirement under the control of the computer, such that an ion within the high-density plasma is acceleratively extracted to form an ion beam current;
measuring, by the Faraday cup, a density of the ion beam current; and
determining, by the computer, whether the density of the ion beam current meets a stability requirement, where the stability requirement is that a density of an ion beam current output by the ion extraction grid meets a density requirement within a set period of time; and
if the density of the ion beam current meets the stability requirement, determining the ion beam current output by the ion extraction grid as a target ion beam current for etching; or
if the density of the ion beam current does not meet the stability requirement, controlling each power supply to perform voltage or power adjustment until the density of the ion beam current meets the stability requirement, and obtaining a target ion beam current.

According to specific embodiments provided in the present disclosure, the present disclosure achieves the following technical effects:

The present disclosure provides a discharge and modulation system and method for a microwave-RF mixed coupled plasma. A process gas is separately delivered to an ECR region and an RF-enhanced discharge chamber. A power of a microwave antenna, a voltage of an electron extraction grid, and an RF voltage are adjusted, such that an electron in an initial plasma formed by discharge of the process gas in the ECR region further collides with the process gas in the RF-enhanced discharge chamber to form a high-density plasma. Whether a density of an ion beam current meets a stability requirement is determined, and a target ion beam current for etching is obtained. This can solve problems of poor adaptability of an existing RF ion source to an electronegative gas, a low ionization rate, a low plasma density, unclear discharge and modulation mechanisms of a microwave ion source, and difficulty in achieving stable control. The discharge and modulation method for a microwave-RF mixed coupled plasma improves adaptability of the process gas, increases a gas ionization rate, and achieves a long-term efficient and stable etching application of an ion source.

### BRIEF DESCRIPTION OF THE DRAWINGS

To describe the technical solutions in the embodiments of the present disclosure or in the prior art more clearly, the following briefly describes the accompanying drawings required for the embodiments. Apparently, the accompanying drawings in the following description show merely some embodiments of the present disclosure, and a person of ordinary skill in the art may still derive other accompanying drawings from these accompanying drawings without creative efforts.

FIG. 1 is a schematic structural diagram of a discharge and modulation system for a microwave-RF mixed coupled plasma according to an embodiment of the present disclosure.

### REFERENCE NUMERALS

1: metal shielding enclosure; 2: first metal microwave shielding shell; 3: microwave antenna; 4: microwave static magnetic field; 5: microwave discharge chamber; 6: electron extraction grid; 7: gas distributor; 8: second metal microwave shielding shell; 9: RF coil; 10: RF-enhanced discharge chamber; 11: ion extraction grid; 12: accelerating grid DC regulated power supply; 13: screen grid DC regulated power supply; 14: RF power supply; 15: electron extraction electrode DC regulated power supply; 16: solid-state microwave power supply; 17: computer; 18: gas distribution system; 19: gas mass flow controller; 20: compressed gas cylinder; 21: gas mixing tank.

### DETAILED DESCRIPTION OF THE EMBODIMENTS

The technical solutions in the embodiments of the present disclosure are clearly and completely described below with reference to the accompanying drawings in the embodiments of the present disclosure. Apparently, the described embodiments are only some rather than all of the embodiments of the present disclosure. All other embodiments obtained by a person of ordinary skill in the art based on the embodiments of the present disclosure without creative efforts shall fall within the protection scope of the present disclosure.

An objective of the present disclosure is to provide a discharge and modulation system and method for a microwave-RF mixed coupled plasma, in order to achieve long-term, efficient, and stable etching of an ion source.

To make the above objectives, features, and advantages of the present disclosure more obvious and easier to understand, the present disclosure will be further described in detail with reference to the accompanying drawings and specific implementations.

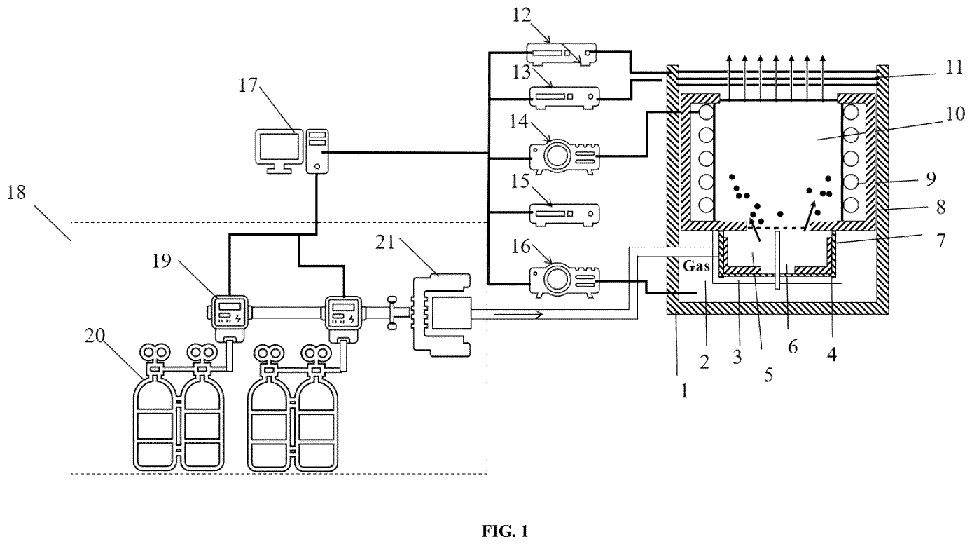

In an exemplary embodiment, as shown in FIG. 1, a discharge and modulation system for a microwave-RF mixed coupled plasma in the embodiments includes: a gas distribution system 18, a plurality of power supplies, an ion beam current generation device, a Faraday cup, and a computer 17. The power supplies are respectively an accelerating grid DC regulated power supply 12, a screen grid DC regulated power supply 13, an RF power supply 14, an electron extraction electrode DC regulated power supply 15, and a solid-state microwave power supply 16. The ion beam current generation device includes: a metal shielding enclosure 1 with an opening at a top, and a first metal microwave shielding shell 2, a microwave antenna 3, a microwave static magnetic field 4, a microwave discharge chamber 5, an electron extraction grid 6, a gas distributor 7, a second metal microwave shielding shell 8, an RF coil 9, an RF-enhanced discharge chamber 10, and an ion extraction grid 11 that are disposed inside the metal shielding enclosure 1. The second metal microwave shielding shell 8, the microwave antenna 3, the microwave static magnetic field 4, the microwave discharge chamber 5, and the electron extraction grid 6 jointly enclose an ECR region. The Faraday cup is disposed in an emission direction of an ion beam current from the ion extraction grid 11. The RF coil 9 surrounds a periphery of the RF-enhanced discharge chamber 10.

The gas distribution system 18, the accelerating grid DC regulated power supply 12, the screen grid DC regulated power supply 13, the RF power supply 14, the electron extraction electrode DC regulated power supply 15, the solid-state microwave power supply 16, and the Faraday cup are all connected to the computer 17. The gas distribution system 18 is connected to the gas distributor 7. The solid-state microwave power supply 16 is connected to the microwave antenna 3, the electron extraction electrode DC regulated power supply 15 is connected to the electron extraction grid 6, the RF power supply 14 is connected to the RF coil 9, and both the accelerating grid DC regulated power supply 12 and the screen grid DC regulated power supply 13 are connected to the ion extraction grid 11.

The computer 17 is configured to obtain an etching requirement and determine a ratio of a process gas based on the etching requirement.

The gas distribution system 18 is configured to store the process gas and deliver the process gas to the gas distributor 7 based on the ratio.

The gas distributor 7 is configured to deliver a portion of the process gas to the ECR region and deliver another portion of the process gas to the RF-enhanced discharge chamber 10.

The solid-state microwave power supply 16 is configured to adjust its own power under control of the computer 17, so as to adjust a power of the microwave antenna 3, such that the process gas in the ECR region discharges to form an initial plasma.

The electron extraction electrode DC regulated power supply 15 is configured to adjust its own voltage under the control of the computer 17, so as to adjust a voltage of the electron extraction grid 6, and extract an electron from the initial plasma into the RF-enhanced discharge chamber 10.

The RF power supply 14 is configured to adjust its own power under the control of the computer 17 to generate an RF voltage, and apply the RF voltage to the RF coil 9, such that the electron further collides with the process gas in the RF-enhanced discharge chamber 10 to form a high-density plasma, where the high-density plasma is a plasma whose density is higher than a density of the initial plasma.

The screen grid DC regulated power supply 13 and the accelerating grid DC regulated power supply 12 are configured to adjust a voltage of the ion extraction grid 11 to a voltage meeting a voltage requirement under the control of the computer 17, such that an ion within the high-density plasma is acceleratively extracted to form an ion beam current.

The Faraday cup is configured to measure a density of the ion beam current.

The computer 17 is further configured to:

determine whether the density of the ion beam current meets a stability requirement, where the stability requirement is that a density of an ion beam current output by the ion extraction grid 11 meets a density requirement within a set period of time; and
if the density of the ion beam current meets the stability requirement, determine the ion beam current output by the ion extraction grid 11 as a target ion beam current for etching; or
if the density of the ion beam current does not meet the stability requirement, control each of the power supplies to perform voltage or power adjustment until the density of the ion beam current meets the stability requirement, and obtain a target ion beam current.

In an exemplary embodiment, total measurement duration is n seconds. Assuming that a beam current density measured at an i^{th} second is jᵢ, beam current stability U_{J} can be expressed as follows:

$${U}_{J} = \frac{max ( {j}_{1} , {j}_{2} , … , {j}_{n} ) - min ( {j}_{1} , {j}_{2} , … , {j}_{n} )}{\frac{1}{n} {\sum }_{i = 1}^{n} {j}_{i}} .$$

When the U_{J} is greater than a set value, the density of the ion beam current output by the ion extraction grid meets the density requirement within the set period of time, and the density of the ion beam current meets the stability requirement.

Different etching processes and etching samples have their own processing requirements. For example, for a 100 mm fused quartz grating, required etching duration is 1 h, and beam current stability is better than 3%. For a meter-level aperture component, required etching duration is 8 h, and beam current stability is better than 3%. For a 1 mm-level sample, required etching duration is fixedly 1 hour, and beam current stability is better than 2%.

In an exemplary embodiment, the gas distribution system 18 includes: a plurality of compressed gas cylinders 20, a plurality of gas mass flow controllers 19, and a gas mixing tank 21. One compressed gas cylinder 20 is connected to one gas mass flow controller 19, the compressed gas cylinders 20 are all connected to the gas mixing tank 21, and the gas mixing tank 21 is connected to the gas distributor 7. The gas mass flow controllers 19 are all connected to the computer 17.

The computer 17 is further configured to:
obtain a gas mass flow that is of a corresponding compressed gas cylinder 20 and collected by each of the gas mass flow controllers 19; and
control each of the compressed gas cylinders 20 to deliver a gas to the gas mixing tank 21 based on the gas mass flow of each of the compressed gas cylinders 20 and the ratio.

The gas mixing tank 21 is configured to mix the gas delivered from each of the compressed gas cylinders 20, obtain the process gas, and deliver the process gas to the gas distributor 7.

In an exemplary embodiment, the gas distributor 7 has circular holes that are uniformly distributed, and the gas distributor 7 simultaneously delivers the process gas to the ECR region and the RF-enhanced discharge chamber 10 through the circular holes.

In an exemplary embodiment, materials of the first metal microwave shielding shell 2 and the second metal microwave shielding shell 8 are stainless steel or aluminum alloy.

In an exemplary embodiment, based on a need, the microwave antenna 3 may be designed as a circular plate, a ring, or another shape that facilitates feeding of microwave energy. A material of the microwave antenna 3 is metal molybdenum or metal copper, and a frequency of the microwave antenna 3 may be selected from 1 GHz to 15 GHz based on a requirement.

In an exemplary embodiment, the microwave static magnetic field 4 is formed by a ring-shaped multipole high-temperature-resistant samarium-cobalt magnet, and magnetic field strength of the microwave static magnetic field 4 is greater than 875 GS.

In an exemplary embodiment, the microwave discharge chamber 5 is made of a quartz or ceramic material.

In an exemplary embodiment, the electron extraction grid 6 is constituted by a graphite or molybdenum grid.

In an exemplary embodiment, the ion extraction grid 11 includes: a screen grid, an accelerating grid, and a decelerating grid that are disposed sequentially from bottom to top.

The accelerating grid DC regulated power supply 12 is connected to the accelerating grid, and the screen grid DC regulated power supply 13 is connected to the screen grid.

In an exemplary embodiment, the ion extraction grid 11 is made of a conductive material, and the conductive material includes molybdenum, stainless steel, and graphite.

In an exemplary embodiment, the RF coil 9 is a copper spiral cylindrical coil.

In an exemplary embodiment, a discharge and modulation method for a microwave-RF mixed coupled plasma in the embodiments is implemented based on the discharge and modulation system for a microwave-RF mixed coupled plasma, and includes:
obtaining, by the computer, an etching requirement, and determining a ratio of a process gas based on the etching requirement;
delivering, by the gas distribution system, the process gas to the gas distributor based on the ratio;
delivering, by the gas distributor, a portion of the process gas to the ECR region, and delivering another portion of the process gas to the RF-enhanced discharge chamber;
adjusting, by the solid-state microwave power supply, its own power under control of the computer, so as to adjust a power of the microwave antenna, such that the process gas in the ECR region discharges to form the initial plasma;
adjusting, by the electron extraction electrode DC regulated power supply, its own voltage under the control of the computer, so as to adjust a voltage of the electron extraction grid, and extracting an electron from the initial plasma into the RF-enhanced discharge chamber;
adjusting, by the RF power supply, its own power under the control of the computer to generate an RF voltage, and applying the RF voltage to the RF coil, such that the electron further collides with the process gas in the RF-enhanced discharge chamber to form a high-density plasma, where the high-density plasma is a plasma whose density is higher than a density of the initial plasma;
adjusting, by the screen grid DC regulated power supply and the accelerating grid DC regulated power supply, a voltage of the ion extraction grid to a voltage meeting a voltage requirement under the control of the computer, such that an ion within the high-density plasma is acceleratively extracted to form an ion beam current;
measuring, by the Faraday cup, a density of the ion beam current; and
determining, by the computer, whether the density of the ion beam current meets a stability requirement, where the stability requirement is that a density of an ion beam current output by the ion extraction grid meets a density requirement within a set period of time; and
if the density of the ion beam current meets the stability requirement, determining the ion beam current output by the ion extraction grid as a target ion beam current for etching; or
if the density of the ion beam current does not meet the stability requirement, controlling each power supply to perform voltage or power adjustment until the density of the ion beam current meets the stability requirement, and obtaining a target ion beam current.

Taking etching of an 85 mm×85 mm×1 mm fused quartz grating substrate with a process gas ratio being 12 sccm for CHF₃, 2 sccm for O₂, and 1 sccm for Ar as an example, the discharge and modulation method for a microwave-RF mixed coupled plasma is further described in detail. Implementation steps are as follows:
Step 1: Determine a type and a ratio of a process gas based on relevant literature or an etching requirement, and use a gas mass flow controller to control a gas introduction amount, namely 12 sccm for the CHF₃, 2 sccm for the O₂, and 1 sccm for the Ar.
Step 2: After the process gas is evenly mixed in the gas mixing tank, open an electromagnetic shut-off valve and direct a mixed gas to the ECR region.
Step 3: Select a microwave band of 2.45 GHZ, adjust the power of the solid-state microwave power supply to 50 W, and adjust the power of the microwave antenna, such that the process gas discharges to form an initial plasma.
Step 4: Adjust the voltage of the electron extraction electrode DC regulated power supply, so as to adjust the voltage of the electron extraction grid, and extract an electron from the initial plasma into the RF-enhanced discharge chamber.
Step 5: Select an RF band of 13.56 MHz, adjust the power of the RF power supply to 100 W to generate an RF voltage, apply the RF voltage to the RF coil, such that the electron further collides with the process gas in the RF-enhanced discharge chamber to form a high-density plasma, observe a plasma status in the RF-enhanced discharge chamber after reflected power drops below 5 W, and perform step 6 after plasma brightness is stable.
Step 6: The screen grid DC regulated power supply and the accelerating grid DC regulated power supply respectively adjust voltages of a screen grid and an accelerating grid in the ion extraction grid to 500 V and −100 V, such that an ion within the high-density plasma is acceleratively extracted to form an ion beam current.
Step 7: Measure, by using the Faraday cup, a density of the ion beam current.
Step 8: Determine whether the density of the ion beam current meets the stability requirement; and if the density of the ion beam current meets the stability requirement, perform step 9; or if the density of the ion beam current does not meet the stability requirement, return to the step 3.
Step 9: Determine an ion beam current output by the ion extraction grid as a target ion beam current for etching.

The technical characteristics of the above embodiments can be employed in arbitrary combinations. To provide a concise description of these embodiments, all possible combinations of all the technical characteristics of the above embodiments may not be described; however, these combinations of the technical characteristics should be construed as falling within the scope defined by this specification as long as no contradiction occurs.

Specific examples are used herein for illustration of the principles and implementations of the present disclosure. The description of the above embodiments is only used to help illustrate the method and the system of the present disclosure and the core principles thereof. In addition, those of ordinary skill in the art can make various modifications in terms of the specific implementations and scope of application in accordance with the teachings of the present disclosure. In conclusion, the content of this specification shall not be construed as a limitation to the present disclosure.

What is claimed is:

1. A discharge and modulation system for a microwave-radio frequency (RF) mixed coupled plasma, comprising: a gas distribution system, a plurality of power supplies, an ion beam current generation device, a Faraday cup, and a computer; wherein the plurality of power supplies are respectively an accelerating grid direct current (DC) regulated power supply, a screen grid DC regulated power supply, an RF power supply, an electron extraction electrode DC regulated power supply, and a solid-state microwave power supply; the ion beam current generation device comprises: a metal shielding enclosure with an opening at a top, and a first metal microwave shielding shell, a microwave antenna, a microwave static magnetic field, a microwave discharge chamber, an electron extraction grid, a gas distributor, a second metal microwave shielding shell, an RF coil, an RF-enhanced discharge chamber, and an ion extraction grid that are disposed inside the metal shielding enclosure; the second metal microwave shielding shell, the microwave antenna, the microwave static magnetic field, the microwave discharge chamber, and the electron extraction grid jointly enclose an Electron Cyclotron Resonance (ECR) region; the Faraday cup is disposed in an emission direction of an ion beam current from the ion extraction grid; and the RF coil surrounds a periphery of the RF-enhanced discharge chamber;
the gas distribution system, the accelerating grid DC regulated power supply, the screen grid DC regulated power supply, the RF power supply, the electron extraction electrode DC regulated power supply, the solid-state microwave power supply, and the Faraday cup are all connected to the computer; the gas distribution system is connected to the gas distributor; and the solid-state microwave power supply is connected to the microwave antenna, the electron extraction electrode DC regulated power supply is connected to the electron extraction grid, the RF power supply is connected to the RF coil, and both the accelerating grid DC regulated power supply and the screen grid DC regulated power supply are connected to the ion extraction grid;
the computer is configured to obtain an etching requirement and determine a ratio of a process gas based on the etching requirement;
the gas distribution system is configured to store the process gas and deliver the process gas to the gas distributor based on the ratio;
the gas distributor is configured to deliver a portion of the process gas to the ECR region and deliver another portion of the process gas to the RF-enhanced discharge chamber;
the solid-state microwave power supply is configured to adjust a power of the solid-state microwave power supply under control of the computer, so as to adjust a power of the microwave antenna, such that the process gas in the ECR region discharges to form an initial plasma;
the electron extraction electrode DC regulated power supply is configured to adjust a voltage of the electron extraction electrode DC regulated power supply under the control of the computer, so as to adjust a voltage of the electron extraction grid, and extract an electron from the initial plasma into the RF-enhanced discharge chamber;
the RF power supply is configured to adjust a power of the RF power supply under the control of the computer to generate an RF voltage, and apply the RF voltage to the RF coil, such that the electron further collides with the process gas in the RF-enhanced discharge chamber to form a high-density plasma, wherein the high-density plasma is a plasma whose density is higher than a density of the initial plasma;
the screen grid DC regulated power supply and the accelerating grid DC regulated power supply are configured to adjust a voltage of the ion extraction grid to a voltage meeting a voltage requirement under the control of the computer, such that an ion within the high-density plasma is acceleratively extracted to form an ion beam current;
the Faraday cup is configured to measure a density of the ion beam current; and
the computer is further configured to:
determine whether the density of the ion beam current meets a stability requirement, wherein the stability requirement is that a density of an ion beam current output by the ion extraction grid meets a density requirement within a set period of time; and
when the density of the ion beam current meets the stability requirement, determine the ion beam current output by the ion extraction grid as a target ion beam current for etching; or
when the density of the ion beam current does not meet the stability requirement, control each of the plurality of power supplies to perform voltage or power adjustment until the density of the ion beam current meets the stability requirement, and obtain a target ion beam current.

2. The discharge and modulation system for a microwave-RF mixed coupled plasma according to claim 1, wherein the gas distribution system comprises: a plurality of compressed gas cylinders, a plurality of gas mass flow controllers, and a gas mixing tank; one compressed gas cylinders is connected to one of the gas mass flow controllers, the plurality of compressed gas cylinders are all connected to the gas mixing tank, and the gas mixing tank is connected to the gas distributor; and the plurality of gas mass flow controllers are all connected to the computer;
the computer is further configured to:
obtain a gas mass flow that is of a corresponding compressed gas cylinder and collected by each of the plurality of gas mass flow controllers; and
control each of the plurality of compressed gas cylinders to deliver a gas to the gas mixing tank based on the gas mass flow of each of the plurality of compressed gas cylinders and the ratio; and
the gas mixing tank is configured to mix the gas delivered from each of the plurality of compressed gas cylinders, obtain the process gas, and deliver the process gas to the gas distributor.

3. The discharge and modulation system for a microwave-RF mixed coupled plasma according to claim 1, wherein the gas distributor has circular holes that are uniformly distributed, and the gas distributor simultaneously delivers the process gas to the ECR region and the RF-enhanced discharge chamber through the circular holes.

4. The discharge and modulation system for a microwave-RF mixed coupled plasma according to claim 1, wherein materials of the first metal microwave shielding shell and the second metal microwave shielding shell are stainless steel or aluminum alloy.

5. The discharge and modulation system for a microwave-RF mixed coupled plasma according to claim 1, wherein the microwave static magnetic field is formed by a ring-shaped multipole high-temperature-resistant samarium-cobalt magnet, and magnetic field strength of the microwave static magnetic field is greater than 875 GS.

6. The discharge and modulation system for a microwave-RF mixed coupled plasma according to claim 1, wherein the microwave discharge chamber is made of a quartz or ceramic material.

7. The discharge and modulation system for a microwave-RF mixed coupled plasma according to claim 1, wherein the electron extraction grid is constituted by a graphite or molybdenum grid.

8. The discharge and modulation system for a microwave-RF mixed coupled plasma according to claim 1, wherein the ion extraction grid comprises: a screen grid, an accelerating grid, and a decelerating grid that are disposed sequentially from bottom to top; and
the accelerating grid DC regulated power supply is connected to the accelerating grid, and the screen grid DC regulated power supply is connected to the screen grid.

9. The discharge and modulation system for a microwave-RF mixed coupled plasma according to claim 1, wherein the ion extraction grid is made of a conductive material, and the conductive material comprises molybdenum, stainless steel, and graphite.

10. A discharge and modulation method for a microwave-RF mixed coupled plasma, implemented based on the discharge and modulation system for a microwave-RF mixed coupled plasma according to claim 1, wherein the discharge and modulation method for a microwave-RF mixed coupled plasma comprises:
obtaining, by the computer, an etching requirement, and determining a ratio of a process gas based on the etching requirement;
delivering, by the gas distribution system, the process gas to the gas distributor based on the ratio;
delivering, by the gas distributor, a portion of the process gas to the ECR region, and delivering another portion of the process gas to the RF-enhanced discharge chamber;
adjusting, by the solid-state microwave power supply, a power of the solid-state microwave power supply under control of the computer, so as to adjust a power of the microwave antenna, such that the process gas in the ECR region discharges to form the initial plasma;
adjusting, by the electron extraction electrode DC regulated power supply, a voltage of the electron extraction electrode DC regulated power supply under the control of the computer, so as to adjust a voltage of the electron extraction grid, and extracting an electron from the initial plasma into the RF-enhanced discharge chamber;
adjusting, by the RF power supply, a power of the RF power supply under the control of the computer to generate an RF voltage, and applying the RF voltage to the RF coil, such that the electron further collides with the process gas in the RF-enhanced discharge chamber to form a high-density plasma, wherein the high-density plasma is a plasma whose density is higher than a density of the initial plasma;
adjusting, by the screen grid DC regulated power supply and the accelerating grid DC regulated power supply, a voltage of the ion extraction grid to a voltage meeting a voltage requirement under the control of the computer, such that an ion within the high-density plasma is acceleratively extracted to form an ion beam current;
measuring, by the Faraday cup, a density of the ion beam current; and
determining, by the computer, whether the density of the ion beam current meets a stability requirement, wherein the stability requirement is that a density of an ion beam current output by the ion extraction grid meets a density requirement within a set period of time; and
when the density of the ion beam current meets the stability requirement, determining the ion beam current output by the ion extraction grid as a target ion beam current for etching; or
when the density of the ion beam current does not meet the stability requirement, controlling each power supply to perform voltage or power adjustment until the density of the ion beam current meets the stability requirement, and obtaining a target ion beam current.

11. The discharge and modulation method for a microwave-RF mixed coupled plasma according to claim 10, wherein the gas distribution system comprises: a plurality of compressed gas cylinders, a plurality of gas mass flow controllers, and a gas mixing tank; one compressed gas cylinders is connected to one of the gas mass flow controllers, the plurality of compressed gas cylinders are all connected to the gas mixing tank, and the gas mixing tank is connected to the gas distributor; and the plurality of gas mass flow controllers are all connected to the computer;
the computer is further configured to:
obtain a gas mass flow that is of a corresponding compressed gas cylinder and collected by each of the plurality of gas mass flow controllers; and
control each of the plurality of compressed gas cylinders to deliver a gas to the gas mixing tank based on the gas mass flow of each of the plurality of compressed gas cylinders and the ratio; and
the gas mixing tank is configured to mix the gas delivered from each of the plurality of compressed gas cylinders, obtain the process gas, and deliver the process gas to the gas distributor.

12. The discharge and modulation method for a microwave-RF mixed coupled plasma according to claim 10, wherein the gas distributor has circular holes that are uniformly distributed, and the gas distributor simultaneously delivers the process gas to the ECR region and the RF-enhanced discharge chamber through the circular holes.

13. The discharge and modulation method for a microwave-RF mixed coupled plasma according to claim 10, wherein materials of the first metal microwave shielding shell and the second metal microwave shielding shell are stainless steel or aluminum alloy.

14. The discharge and modulation method for a microwave-RF mixed coupled plasma according to claim 10, wherein the microwave static magnetic field is formed by a ring-shaped multipole high-temperature-resistant samarium-cobalt magnet, and magnetic field strength of the microwave static magnetic field is greater than 875 GS.

15. The discharge and modulation method for a microwave-RF mixed coupled plasma according to claim 10, wherein the microwave discharge chamber is made of a quartz or ceramic material.

16. The discharge and modulation method for a microwave-RF mixed coupled plasma according to claim 10, wherein the electron extraction grid is constituted by a graphite or molybdenum grid.

17. The discharge and modulation method for a microwave-RF mixed coupled plasma according to claim 10, wherein the ion extraction grid comprises: a screen grid, an accelerating grid, and a decelerating grid that are disposed sequentially from bottom to top; and
the accelerating grid DC regulated power supply is connected to the accelerating grid, and the screen grid DC regulated power supply is connected to the screen grid.

18. The discharge and modulation method for a microwave-RF mixed coupled plasma according to claim 10, wherein the ion extraction grid is made of a conductive material, and the conductive material comprises molybdenum, stainless steel, and graphite.
